(19) United States
(12) Patent Application Publication
(10) Pub. No.: US 2025/0107363 A1
(43) Pub. Date: Mar. 27, 2025

(54) DISPLAY APPARATUS

(71) Applicant: Samsung Display Co., LTD., Yongin-si (KR)

(72) Inventor: Myunghwan KIM, Yongin-si (KR)

(21) Appl. No.: 18/743,512

(22) Filed: Jun. 14, 2024

(30) Foreign Application Priority Data
Sep. 21, 2023 (KR) 10-2023-0126402

(51) Int. Cl. H10K 59/131; H10K 59/80

(52) U.S. Cl. CPC H10K 59/131; H10K 59/873

(57) ABSTRACT

A display apparatus includes a substrate, a display layer located on a first surface of the substrate and including a display element, and a protective film on a second surface of the substrate, the second surface of the substrate being opposite to the first surface of the substrate. The protective film includes a base layer that is transparent, a first conductive layer located on a first surface of the base layer, and a second conductive layer located on a second surface of the base layer, the second surface of the base layer being opposite to the first surface of the base layer. The protective film includes an adhesive layer between the first conductive layer and the substrate. The adhesive layer includes at least one of conductive molecules, polar molecules, and zwitterions.

This application claims priority to Korean Patent Application No. 10-2023-0126402, filed on Sep. 21, 2023, and all the benefits accruing therefrom under 35 U.S.C. § 119, the content of which in its entirety is herein incorporated by reference.

### BACKGROUND

### 1. Field

One or more embodiments relate to a display apparatus.

### 2. Description of the Related Art

Display apparatuses may visually display data. A display apparatus may include a substrate divided into a display area and a non-display area. A plurality of pixel areas may be defined in the display area. In some cases, a thin-film transistor corresponding to each of the pixel areas and a pixel electrode electrically connected to the thin-film transistor may be provided in the display area. Various conductive layers, such as, for example, wiring lines that transmit electrical signals to the display area, may be provided in the non-display area.

By bending at least a portion of the display apparatus, visibility from various angles may be improved or the area of the non-display area may be reduced.

### SUMMARY

One or more embodiments include a protective film disposed below a display panel. Embodiments set forth herein are examples, and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate, a display layer located on a first surface of the substrate and including a display element, and a protective film located on a second surface of the substrate, wherein the second surface of the substrate is opposite to the first surface of the substrate. The protective film includes a base layer that is transparent, a first conductive layer located on a first surface of the base layer, a second conductive layer located on a second surface of the base layer, wherein the second surface of the base layer is opposite to the first surface of the base layer, and an adhesive layer between the first conductive layer and the substrate, wherein the adhesive layer includes at least one of conductive molecules, polar molecules, and zwitterions.

The base layer may include polyethylene terephthalate or polyimide.

The base layer may be absent organic nanoparticles and inorganic nanoparticles.

The surface resistance of the first conductive layer may be about 30 Ω/sq to about 10⁶ Ω/sq.

The first conductive layer and the second conductive layer may each include a conductive polymer or a transparent conductive oxide.

A thickness of each of the first conductive layer and the second conductive layer may be about 0.01 μm to about 0.5 μm.

A thickness of the adhesive layer may be about 3 μm to about 30 μm.

The surface resistance of the adhesive layer may be about 10³ Ω/sq to about 10¹⁰ Ω/sq.

The fluorine (F) content of the protective film may be less than 0.25 ppb.

According to one or more embodiments, a display apparatus includes a substrate, a display element disposed on a front surface of the substrate, an encapsulation member covering the display element, and a protective film disposed on a rear surface of the substrate, wherein the protective film includes a base layer that is transparent, a first conductive layer disposed on a front surface of the base layer, a second conductive layer disposed on a rear surface of the base layer, and an adhesive layer between the first conductive layer and the substrate, wherein the adhesive layer includes at least one of conductive molecules, polar molecules, and zwitterions, and the surface resistance of the adhesive layer is about 10¹⁰ Ω/sq or less.

The substrate may include a first area facing a first direction, a second area extending from the first area and facing a second direction different from the first direction, and a third area located between the first area and the second area, the display element may be disposed on the first area, and the protective film may include a portion located in the first area and another portion spaced apart from the portion and located in the second area.

The display apparatus may further include an optical member on the encapsulation member, and a window on the optical member.

The base layer may include polyethylene terephthalate or polyimide.

The base layer may be absent organic nanoparticles and inorganic nanoparticles.

The surface resistance of the first conductive layer may be about 30 Ω/sq to about 10⁶ Ω/sq.

The first conductive layer and the second conductive layer may each include a conductive polymer or a transparent conductive oxide.

The first conductive layer and the second conductive layer may each have a thickness of about 0.01 μm to about 0.5 μm.

The adhesive layer may have a thickness of about 3 μm to about 30 μm.

The surface resistance of the adhesive layer may be about 10³ Ω/sq to about 10¹⁰ Ω/sq.

The fluorine (F) content of the protective film may be less than 0.25 ppb.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2 is a schematic perspective view of a portion of a display apparatus according to an embodiment;

FIG. 3 is an equivalent circuit diagram of a pixel that may be included in a display apparatus according to an embodiment;

FIG. 4 is a portion of a cross-sectional view of the display apparatus taken along line I-I′ of FIG. 1;

FIG. 5 is a schematic cross-sectional view of a portion of a display apparatus according to an embodiment;

FIG. 6 is a cross-sectional view of a protective film included in a display apparatus according to an embodiment;

FIG. 7 is a cross-sectional view of a protective film included in a display apparatus according to an embodiment;

FIG. 8 is a cross-sectional view of a protective film included in a display apparatus according to an embodiment; and

FIG. 9 is a cross-sectional view of a protective film included in a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

In the example embodiments described herein, it will be understood that although the terms “first,” “second,” and the like may be used herein to describe various components, these components should not be limited by these terms. These terms are only used to distinguish one component from another.

In the example embodiments described herein, as used herein, the singular forms are intended to include the plural forms as well, unless the context clearly indicates otherwise.

In the example embodiments described herein, it will be further understood that the terms “include”, “comprise”, and/or “have” used herein specify the presence of stated features or components, but do not preclude the presence or addition of one or more other features or components.

In the example embodiments described herein, it will be understood that when a layer, region, or component is referred to as being “formed on” another layer, region, or component, the layer, region, or component can be directly or indirectly formed on the other layer, region, or component. That is, for example, intervening layers, regions, or components may be present.

In the specification, the expression “A and/or B” may include A, B, or A and B. Furthermore, the expression “at least one of A and B” may include A, B, or A and B.

As used herein, descriptions of a wiring referred to as “extending in a first direction or a second direction” may mean that the wiring not only extends in a straight line shape but also extends in a zigzag or in a curve in the first direction or the second direction.

As used herein, “in a plan view” means that an objective portion is viewed from above, and “in a cross-sectional view” means that a cross-section of an objective portion taken vertically is viewed from a lateral side.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

The term “substantially equal,” as used herein, means approximately or actually equal (e.g., within a threshold percent of equal, within a threshold difference amount).

Hereinafter, embodiments of the disclosure are described in detail with reference to the accompanying drawings. When description is made with reference to the drawings, like reference numerals are used for like or corresponding elements.

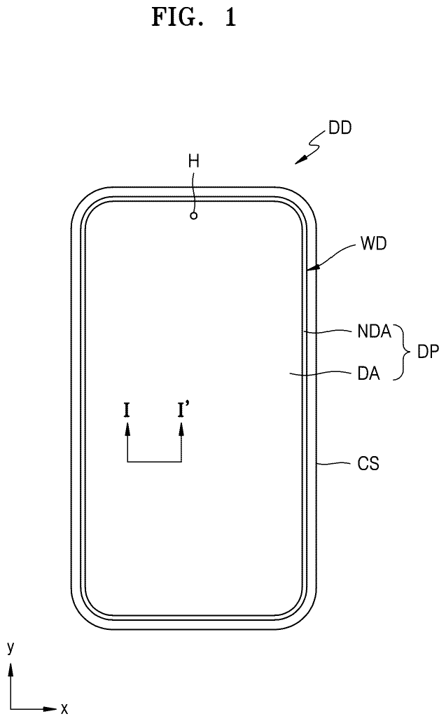

FIG. 1 is a schematic plan view of a display apparatus DD according to an embodiment.

Referring to FIG. 1, the display apparatus DD may include a display panel DP for displaying an image, a window WD, and a case CS to protect the display panel DP.

The display panel DP may display arbitrary visual information, such as, for example, text, video, photos, and 2-dimensional or 3-dimensional images. Hereinafter, general visual information is referred to as an “image.” In accordance with one or more embodiments of the present disclosure, the type, structure, and/or shape of the display panel DP are not particularly limited. For example, the display panel DP may be a self-emitting display panel, such as, for example, an Organic Light-Emitting Display panel (OLED panel), or may be a non-emissive display panel, such as, for example, a Liquid Crystal Display panel (LCD panel), an Electro-Phoretic Display panel (EPD panel), and an Electro-Wetting Display panel (EWD panel). In an example in which a non-emissive display panel is used as the display panel DP of the display apparatus DD, the display apparatus DD may be provided with a light source unit (for example, a backlight unit) for supplying light to the display panel DP.

As an example, the display panel DP may include a display area DA and a non-display area NDA located around the display area DA. The display area DA may include a plurality of pixels to display an image. In an embodiment, a light-transmitting hole area H (e.g., a non-pixel area in which pixels are not arranged, or a low-resolution area in which pixels are arranged at low resolution) corresponding to a camera, an infrared ray (IR) sensor, or the like may be formed in the display area DA. The non-display area NDA may be disposed on at least one side of the display area DA such that the non-display area NDA partially or completely surrounds the display area DA. In the non-display area NDA, wire lines, pads, and/or at least one driving circuit for driving pixels of the display area DA may be arranged.

The window WD and the case CS are coupled to the display panel DP to protect the display panel DP from external shock. As an example, the window WD may be located on the front of the display apparatus DD and be placed on the top of the display panel DP, and the case CS may be located on the side and/or back of the display apparatus DD such that the case CS surrounds the side and/or back of the display panel DP.

The display apparatus DD may include at least one type of sensor supportive of providing various functions. As an example, the display apparatus DD may include an IR sensor (not shown) or a fingerprint sensor (not shown) supportive of providing a biometric information authentication function. In some aspects, the display apparatus DD may further include a sensor supportive of providing a touch input function.

For example, the display apparatus DD may include an IR sensor provided on the back of the display panel DP, and the IR sensor may overlap an area of the display area DA. However, the position of the IR sensor may vary based on embodiments. As an example, the IR sensor may be provided such that the IR sensor overlaps the non-display area NDA (e.g., the light-transmitting hole area H).

The display apparatus DD may have various shapes. For example, the display apparatus DD may have a rectangular shape in which the horizontal length (or width) in an x direction is less than the vertical length in a y direction, but is not limited thereto. For example, in another embodiment, the display apparatus DD may have a rectangular shape in which the horizontal length is greater than the vertical length, a square shape in which the horizontal length is substantially equal to the vertical length, or various other shapes. For example, the display apparatus DD may have various polygonal shapes, circular shapes, elliptical shapes, and/or combinations of the shapes. In some aspects, the display apparatus DD may have angled corners or round corners.

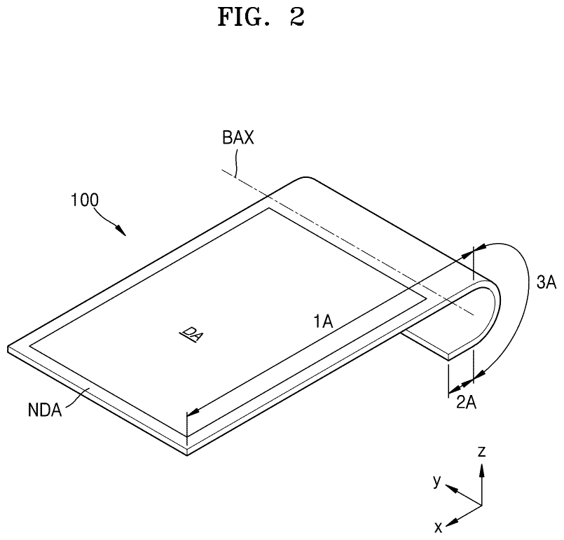

FIG. 2 is a schematic perspective view of a portion of a display apparatus according to an embodiment.

In accordance with one or more embodiments of the present disclosure, a portion of the substrate 100 may be bendable. Referring to FIG. 2, a portion of a substrate 100, which is a portion of the display apparatus, is illustrated in a bent state, and thus, the portion of the display apparatus may have a bent shape similar to the substrate 100. Described herein with reference to FIG. 2 are with respect to a bent state of the portion of the substrate 100.

The substrate 100 may have a first area 1A facing a first direction, a second area 2A extending from the first area 1A and (e.g., in the bent state) facing a second direction different from the first direction, and a third area 3A located between the first area 1A and the second area 2A. As illustrated in FIG. 2, when the first direction toward which the first area 1A faces is a +z direction, the second direction toward which the second area 2A faces may be a −z direction. The first area 1A and the second area 2A may face opposite directions. That is, one side of the first area 1A and one side of the second area 2A may be positioned parallel to each other and may be provided in a folded state to face each other. However, the disclosure is not limited thereto and may include cases where the first area 1A and the second area 2A do not face the same direction.

The third area 3A may be located between the first area 1A and the second area 2A. As illustrated in FIG. 2, as an example, the third area 3A may be bent around a bending axis BAX extending in a y direction perpendicular to the first direction (z direction). In FIG. 2, the substrate 100 is shown to be bent with the same radius of curvature based on the bending axis BAX. However, the disclosure is not limited thereto. The substrate 100 may be bent according to an irregular radius of curvature around the bending axis BAX.

The third area 3A may be arranged such that the third area 3A is continuous with the first area 1A, and the second area 2A may be arranged such that the second area 2A is continuous with the third area 3A. The third area 3A may be formed integrally with the first area 1A such that the third area 3A is continuous with the first area 1A, but is not limited thereto.

In an embodiment, the first area 1A may be provided in the display area DA and/or at least a portion of the non-display area NDA. The third area 3A may be provided in the non-display area NDA. For example, as illustrated in FIG. 2, the non-display area NDA may include a protruding area that protrudes from a portion of the non-display area NDA in at least one direction (for example, −x direction), and may be folded or bent in the protruding area. As an example, the first area 1A may be provided in the display area DA and/or the non-display area NDA around the display area DA, and the third area 3A and the second area 2A may be provided in the protruding area of the non-display area NDA.

The protruding area of the non-display area NDA may be folded (or bent or rolled) along a fold line, and the width of a bezel may be reduced by folding (or bending) the protruding area of the non-display area NDA.

The substrate 100 may include various materials that are flexible or bendable. For example, the substrate 100 may include a polymer resin, such as, for example, polyethersulphone, polyacrylate, polyetherimide, polyethylene naphthalate, polyphenylene sulfide, polyarylate, polyimide, or cellulose acetate propionate. The substrate 100 may have a single-layered or multi-layered structure including the materials described above, and the multi-layered structure may further include an inorganic layer.

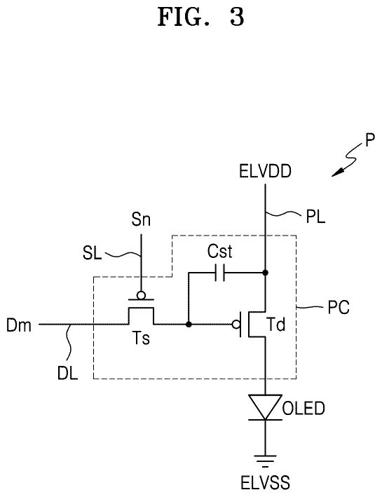

FIG. 3 is an equivalent circuit diagram of a pixel that may be included in a display apparatus according to an embodiment.

Referring to FIG. 3, each pixel P may include a pixel circuit PC connected to a scan line SL and a data line DL, and each pixel P may include an organic light-emitting device OLED connected to the pixel circuit PC.

The pixel circuit PC may include a driving thin-film transistor Td, a switching thin-film transistor Ts, and a storage capacitor Cst. The switching thin-film transistor Ts may be connected to the scan line SL and the data line DL. The switching thin-film transistor Ts may be configured to transmit a data signal Dm input through the data line DL to the driving thin-film transistor Td according to a scan signal Sn input through the scan line SL.

The storage capacitor Cst may be connected to the switching thin-film transistor Ts and a driving voltage line PL. The storage capacitor Cst may store a voltage corresponding to a difference between a voltage received from the switching thin-film transistor Ts and a first power supply voltage ELVDD (or a driving voltage) supplied to the driving voltage line PL.

The driving thin-film transistor Td may be connected to the driving voltage line PL and the storage capacitor Cst. The driving thin-film transistor Td may be configured to control driving current flowing through the organic light-emitting device OLED from the driving voltage line PL in response to a value of the voltage stored in the storage capacitor Cst. The organic light-emitting device OLED may emit light having a certain brightness based on the driving current.

Although an example case where the pixel circuit PC includes two thin-film transistors and one storage capacitor is illustrated in FIG. 3, embodiments supported by the present disclosure are not limited thereto. In another embodiment, the pixel circuit PC may include, for example, seven thin-film transistors and one storage capacitor. In another embodiment, the pixel circuit PC may include two or more storage capacitors.

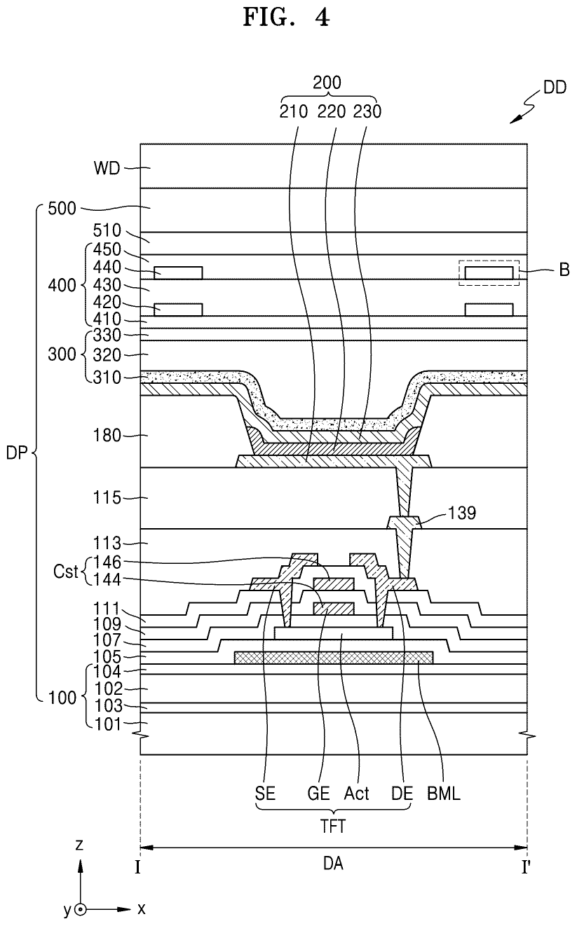

FIG. 4 is a portion of a cross-sectional view of the display apparatus DD taken along line I-I′ of FIG. 1.

Referring to FIG. 4, the display apparatus DD may include a display panel DP and a window WD on the display panel DP. A thin-film transistor TFT and a display element 200 may be disposed on a substrate 100 of the display apparatus DD.

The substrate 100 may include various materials that are flexible, bendable, or rollable. For example, the substrate 100 may include a polymer resin, such as, for example, polyethersulphone, polyacrylate, polyetherimide, polyethylene naphthalate, polyethyleneterephthalate, polyphenylene sulfide, polyarylate, polyimide, polycarbonate, or cellulose acetate propionate.

The substrate 100 includes a first base layer 101, a second base layer 102 disposed on the first base layer 101, a first barrier layer 103 between the first base layer 101 and the second base layer 102, and a second barrier layer 104 on the second base layer 102. The first barrier layer 103 and the second barrier layer 104 may each include at least one inorganic insulating material selected from the group including silicon oxide, silicon nitride, silicon oxynitride, aluminum oxide, titanium oxide, tantalum oxide, hafnium oxide, and zinc oxide. The second barrier layer 104 may include a single layer or multilayer including the aforementioned inorganic insulating material. In some embodiments, the second barrier layer 104 may be omitted.

A buffer layer 105 may be disposed on the second barrier layer 104. The buffer layer 105 may be located on the substrate 100 and reduce or block penetration of foreign materials, moisture, or external air from the bottom of the substrate 100 and may provide a flat surface on the substrate 100. The buffer layer 105 may include an inorganic material, such as, for example, oxide or nitride, an organic material, or an organic-inorganic composite, and may have a single-layered or multi-layered structure including an inorganic material, an organic material, or a combination of one or more inorganic materials and one or more organic materials.

A lower metal layer BML may be disposed between the second barrier layer 104 and the buffer layer 105. The lower metal layer BML may overlap the thin-film transistor TFT disposed above the lower metal layer BML.

The thin-film transistor TFT may be disposed on the buffer layer 105. The thin-film transistor TFT may include a semiconductor layer Act, a gate electrode GE overlapping the semiconductor layer Act, and a source electrode SE and a drain electrode DE, which are electrically connected to the semiconductor layer Act. The thin-film transistor TFT may be connected to the display element 200 and may drive the display element 200.

The semiconductor layer Act may be disposed on the buffer layer 105 and may include a channel region overlapping the gate electrode GE. The semiconductor layer Act may include a source region and a drain region, which are disposed on both sides of the channel region and include a higher concentration of impurities than the channel region. In this example case, the impurities may include N-type impurities or P-type impurities. The source region and the drain region may be electrically connected to the source electrode SE and the drain electrode DE, respectively.

The semiconductor layer Act may include an oxide semiconductor and/or a silicon semiconductor. In an example in which the semiconductor layer Act includes an oxide semiconductor, the oxide semiconductor may include, for example, an oxide of at least one material selected from the group including indium (In), gallium (Ga), tin (Sn), zirconium (Zr), vanadium (V), hafnium (Hf), cadmium (Cd), germanium (Ge), chromium (Cr), titanium (Ti), and zinc (Zn). For example, the semiconductor layer Act may include InSnZnO (ITZO), InGaZnO (IGZO), or the like. In an example in which the semiconductor layer Act includes a silicon semiconductor, the silicon semiconductor may include, for example, amorphous silicon or low temperature poly-silicon (LTPS) obtained by crystallizing amorphous silicon.

A first insulating layer 107 may be disposed on the semiconductor layer Act. The first insulating layer 107 may include at least one inorganic insulating material selected from the group including silicon oxide, silicon nitride, silicon oxynitride, aluminum oxide, titanium oxide, tantalum oxide, hafnium oxide, and zinc oxide. The first insulating layer 107 may include a single layer or multilayer including the aforementioned inorganic insulating material.

The gate electrode GE may be disposed on the first insulating layer 107. The gate electrode GE may include one or more metals selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) and may be formed as a single layer or multilayer. The gate electrode GE may be connected to a gate line that applies an electrical signal to the gate electrode GE.

A second insulating layer 109 may be disposed on the gate electrode GE. The second insulating layer 109 may include at least one inorganic insulating material selected from the group including silicon oxide, silicon nitride, silicon oxynitride, aluminum oxide, titanium oxide, tantalum oxide, hafnium oxide, and zinc oxide. The second insulating layer 109 may include a single layer or multilayer including the aforementioned inorganic insulating material.

A storage capacitor Cst may be disposed on the first insulating layer 107. The storage capacitor Cst may include a lower electrode 144 and an upper electrode 146 that overlaps the lower electrode 144. The lower electrode 144 of the storage capacitor Cst and the upper electrode 146 of the storage capacitor Cst may overlap each other with the second insulating layer 109 therebetween.

The lower electrode 144 of the storage capacitor Cst may overlap the gate electrode GE of the thin-film transistor TFT and may be arranged integrally with the gate electrode GE of the thin-film transistor TFT. In another embodiment, the storage capacitor Cst may not overlap the thin-film transistor TFT, and the lower electrode 144 of the storage capacitor Cst may be an independent component separate from the gate electrode GE of the thin-film transistor TFT.

The upper electrode 146 of the storage capacitor Cst may include Al, Pt, Pd, Ag, Mg, Au, Ni, Nd, Ir, Cr, Li, Ca, Mo, Ti, W, and/or Cu and may include a single layer or multilayer including the aforementioned material (e.g., one or more of Al, Pt, Pd, Ag, Mg, Au, Ni, Nd, Ir, Cr, Li, Ca, Mo, Ti, W, and Cu).

A third insulating layer 111 may be disposed on the upper electrode 146 of the storage capacitor Cst. The third insulating layer 111 may include at least one inorganic insulating material selected from the group including silicon oxide, silicon nitride, silicon oxynitride, aluminum oxide, titanium oxide, tantalum oxide, hafnium oxide, and zinc oxide. The third insulating layer 111 may include a single layer or multilayer including the aforementioned inorganic insulating material.

The source electrode SE and the drain electrode DE may be disposed on the third insulating layer 111. The source electrode SE and the drain electrode DE may each include a conductive material including Mo, Al, Cu, Ti, or the like and may include multiple layers or a single layer including the aforementioned conductive material. Each of the source electrode SE and the drain electrode DE may have a multi-layered structure including Ti/Al/Ti layers.

A first planarization layer 113 may be disposed on the source electrode SE and the drain electrode DE. The first planarization layer 113 may be formed as a single layer or multilayer film including an organic material or an inorganic material. In an embodiment, the first planarization layer 113 may include a general-purpose polymer, such as, for example, benzocyclobutene (BCB), polyimide (PI), hexamethyldisiloxane (HMDSO), polymethylmethacrylate (PMMA), or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend of any combination of the general-purpose polymers and/or polymer derivatives. The first planarization layer 113 may include silicon oxide, silicon nitride, silicon oxynitride, aluminum oxide, titanium oxide, tantalum oxide, hafnium oxide, or zinc oxide. After the first planarization layer 113 is formed, chemical mechanical polishing supportive of providing a flat top surface may be performed.

A connection electrode 139 may be disposed on the first planarization layer 113. The connection electrode 139 may include Al, Cu, Ti, or the like, and may be formed as a multilayer or single layer. The connection electrode 139 may have a multi-layered structure including Ti/Al/Ti layers.

A second planarization layer 115 may be disposed on the connection electrode 139. The second planarization layer 115 may be formed as a single layer or multilayer film including an organic material or an inorganic material. The second planarization layer 115 may include the same material as the first planarization layer 113. The second planarization layer 115 may include a different material from the first planarization layer 113.

The display element 200 including a pixel electrode 210, an intermediate layer 220, and an opposite electrode 230 may be disposed on the second planarization layer 115. In an example, the display element 200 including the pixel electrode 210, the intermediate layer 220, and the opposite electrode 230 may be an organic light-emitting device.

The pixel electrode 210 may be electrically connected to the connection electrode 139 through a contact hole passing through the second planarization layer 115, and the connection electrode 139 may be electrically connected to the source electrode SE or drain electrode DE of the thin-film transistor TFT through a contact hole passing through the first planarization layer 113, and thus, the display element 200 may be electrically connected to the thin-film transistor TFT.

A pixel electrode 210 may be disposed on the second planarization layer 115. The pixel electrode 210 may be a (semi-) transmissive electrode or a reflective electrode. The pixel electrode 210 may include a reflective layer including Al, Pt, Pd, Ag, Mg, Au, Ni, Nd, Ir, Cr, Li, Ca, Mo, Ti, W, Cu, or a compound of any of Al, Pt, Pd, Ag, Mg, Au, Ni, Nd, Ir, Cr, Li, Ca, Mo, Ti, W, or Cu. The pixel electrode 210 may include a transparent or translucent electrode layer formed on the reflective layer. The transparent or translucent electrode layer may include at least one selected from the group including indium tin oxide, indium zinc oxide, zinc oxide, indium oxide, indium gallium oxide, and aluminum zinc oxide. For example, the pixel electrode 210 may have a stacked structure including ITO/Ag/ITO layers.

A bank layer 180 may be disposed on the second planarization layer 115, and the bank layer 180 may have an opening that exposes at least a portion of the pixel electrode 210. An area exposed by the opening of the bank layer 180 may be defined as an emission area. The surrounding area of emission areas may be a non-emission area, and the non-emission area may surround the emission areas. That is, the display area DA may include a plurality of emission areas and a non-emission area surrounding the emission areas. The bank layer 180 may increase the distance between the edge of the pixel electrode 210 and the opposite electrode 230 above the pixel electrode 210, thereby preventing arcs or other effects from occurring at the edge of the pixel electrode 210. The bank layer 180 may include an organic insulating material, such as, for example, polyimide, polyamide, acrylic resin, benzocyclobutene, HMDSO, or phenol resin, and may be formed by a method, such as, for example, spin coating.

The intermediate layer 220 may be disposed on the pixel electrode 210 that is at least partially exposed by the bank layer 180. For example, the intermediate layer 220 may be disposed on the portion of the pixel electrode 210 that is exposed by the bank layer 180. The intermediate layer 220 may include an emission layer. The intermediate layer 220 may include a first functional layer and/or a second functional layer selectively disposed below and above the emission layer.

The intermediate layer 220 may be disposed on the pixel electrode 210 that is at least partially exposed by the bank layer 180. More specifically, the emission layer of the intermediate layer 220 may be disposed on the pixel electrode 210 at least partially exposed by the bank layer 180. For example, emission layer may be disposed on the portion of the pixel electrode 210 that is exposed by the bank layer 180.

The first functional layer may include a hole injection layer and/or a hole transport layer, and the second functional layer may include an electron transport layer and/or an electron injection layer.

The emission layer may include an organic material containing a fluorescent or phosphorescent material that emits red, green, blue, or white light. The emission layer may include a low-molecular organic material or a high-molecular organic material.

In an example in which the emission layer includes a low-molecular organic material, the intermediate layer 220 may have a structure in which a hole injection layer, a hole transport layer, an emission layer, an electron transport layer, an electron injection layer, or the like (e.g., other layers of the intermediate layer 220) are stacked in a single or composite structure, and the low-molecular organic material may include various organic materials, such as, for example, copper phthalocyanine (CuPc), N,N′-di(napthalene-1-yl)-N,N′-diphenyl-benzidine (NPB), and tris-8-hydroxyquinoline aluminum (Alq3)). In some embodiments, the layers described with reference to the intermediate layer 220 may be formed by vacuum deposition.

In an example in which the emission layer includes a high-molecular organic material, the intermediate layer 220 may generally have a structure including a hole transport layer and an emission layer. In some aspects, the hole transport layer may include PEDOT, and the emission layer may include a high molecular weight material, such as, for example, poly-phenylene vinylene (PPV) or polyfluorene. This emission layer may be formed by screen printing, inkjet printing, laser induced thermal imaging (LITI), or the like.

The opposite electrode 230 may be disposed on the intermediate layer 220. The opposite electrode 230 may be disposed on the intermediate layer 220 to entirely cover the intermediate layer 220. The opposite electrode 230 may be disposed over the display area and may be arranged to entirely cover the display area. That is, the opposite electrode 230 may be integrally formed as a single body through the display panel such that the opposite electrode 230 covers a plurality of pixels arranged in the display area by using an open mask.

The opposite electrode 230 may include a conductive material with a low work function. For example, the opposite electrode 230 may include a (semi-) transparent layer including Ag, Mg, Al, Pt, Pd, Au, Ni, Nd, Ir, Cr, Li, Ca, or an alloy of Ag, Mg, Al, Pt, Pd, Au, Ni, Nd, Ir, Cr, Li, or Ca. Alternatively, or additionally, the opposite electrode 230 may further include a layer, such as, for example, an ITO, IZO, ZnO, or In₂O₃ layer, on the (semi-) transparent layer including the aforementioned material.

A thin-film encapsulation layer 300, which is an encapsulation member, may be disposed on the display element 200, for example, on the opposite electrode 230. The thin-film encapsulation layer 300 may include at least one inorganic encapsulation layer and at least one organic encapsulation layer. The thin-film encapsulation layer 300 may prevent oxygen or moisture from penetrating into the intermediate layer 220 including the emission layer and the opposite electrode 230. In an example, the thin-film encapsulation layer 300 may include a first inorganic encapsulation layer 310 disposed on the opposite electrode 230, an organic encapsulation layer 320 disposed on the first inorganic encapsulation layer 310, and a second inorganic encapsulation layer 330 disposed on the organic encapsulation layer 320. The first inorganic encapsulation layer 310 and the second inorganic encapsulation layer 330 may each include silicon nitride, silicon oxynitride, silicon oxide, titanium oxide, or aluminum oxide. The organic encapsulation layer 320 may include acrylic resin, epoxy resin, phenolic resin, polyamide resin, polyimide resin, or the like.

This thin-film encapsulation layer 300 may extend outside the display area DA. In some embodiments, outside the display area DA, the first inorganic encapsulation layer 310 and the second inorganic encapsulation layer 330 may be in contact with each other.

A sensor layer 400 may be disposed on the thin-film encapsulation layer 300. The sensor layer 400 may include a first sensor insulating layer 410, a second sensor insulating layer 430, and a third sensor insulating layer 450. In some aspects, the sensor layer 400 may include a first sensor electrode 420 disposed between the first sensor insulating layer 410 and the second sensor insulating layer 430, and a second sensor electrode 440 disposed between the second sensor insulating layer 430 and the third sensor insulating layer 450. The first sensor electrode 420 and the second sensor electrode 440 may include driving electrodes and sensing electrodes. Although not shown in the drawings, the first sensor electrode 420 and the second sensor electrode 440 may be electrically connected to each other through a contact hole defined in the second sensor insulating layer 430.

The first sensor insulating layer 410 may include at least one inorganic insulating material selected from the group including silicon oxide, silicon nitride, silicon oxynitride, aluminum oxide, titanium oxide, tantalum oxide, hafnium oxide, and zinc oxide. The first sensor insulating layer 410 may have a single-layered or multi-layered structure. In another embodiment, the first sensor insulating layer 410 may include at least one of acrylic resin, methacrylic resin, polyisoprene, vinyl resin, epoxy resin, urethane resin, cellulose resin, siloxane resin, polyimide resin, polyamide resin, and perylene resin. In some embodiments, the first sensor insulating layer 410 may be omitted.

The second sensor insulating layer 430 may include at least one inorganic insulating material selected from the group including silicon oxide, silicon nitride, silicon oxynitride, aluminum oxide, titanium oxide, tantalum oxide, hafnium oxide, and zinc oxide. The first sensor insulating layer 410 may have a single-layered or multi-layered structure. In another embodiment, the second sensor insulating layer 430 may include at least one of acrylic resin, methacrylic resin, polyisoprene, vinyl resin, epoxy resin, urethane resin, cellulose resin, siloxane resin, polyimide resin, polyamide resin, and perylene resin.

A polarizing film 500, which is an optical member, may be located on the sensor layer 400. The polarizing film 500 may be attached to the sensor layer 400 by a light-transmitting adhesive layer 510. The polarizing film 500 may reduce external light reflection. For example, when external light passes through the polarizing film 500, is reflected from the upper surface of the opposite electrode 230, and passes through the polarizing film 500 again, the phase of the external light may change due to the external light passing through the polarizing film 500 twice. As a result, destructive interference may occur in which the phase of a reflected light is different from the phase of the external light entering the polarizing film 500. Aspects of the display apparatus DD and display panel DP as described herein support features capable of improving visibility by reducing external light reflection. The light-transmitting adhesive layer 510 and the polarizing film 500 may be provided such that the light-transmitting adhesive layer 510 and the polarizing film 500 overlap a portion of the non-display area NDA in addition to the display area DA.

In some embodiments, the display apparatus may omit or be absent the polarizing film 500. For example, in some embodiments, the polarizing film 500 may be omitted or replaced with other components. For example, the polarizing film 500 may be omitted and external light reflection may be reduced by using a black matrix and a color filter.

The window WD may be provided on the polarizing film 500. The window WD may protect the display panel DP from external shock and provide an input surface and/or a display surface to a user. In an embodiment, the window WD may be coupled to the polarizing film 500 through an optically transparent adhesive member.

The window WD may be formed to be rigid or flexible using glass or plastic. In some aspects, the window WD may have a single-layered or multi-layered structure. In an example in which the window WD has a multi-layered structure, the window WD may be formed through a continuous process or an adhesion process using an adhesive layer.

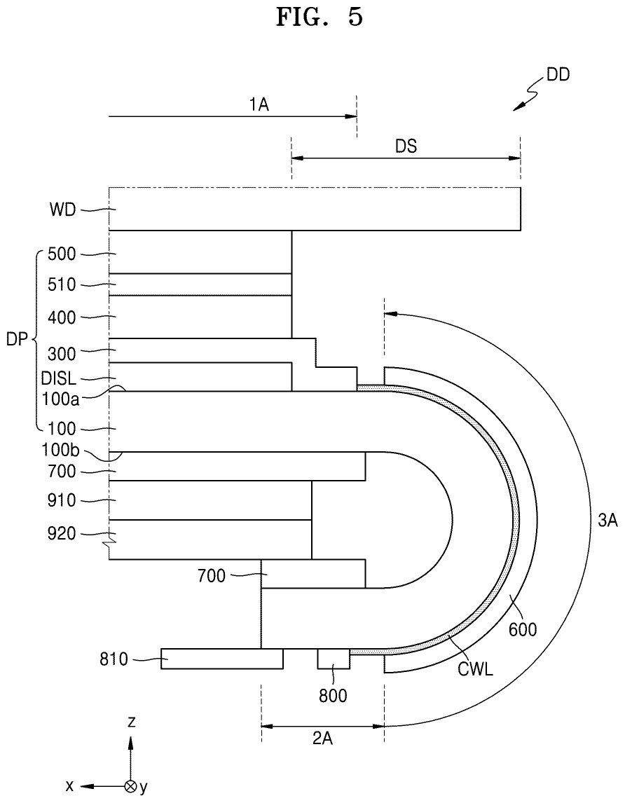

FIG. 5 is a schematic cross-sectional view of a portion of a display apparatus DD according to an embodiment.

Referring to FIG. 5, the display apparatus DD according to an embodiment may include a substrate 100, a display layer DISL, a thin-film encapsulation layer 300, a sensor layer 400, a light-transmitting adhesive layer 510, a polarizing film 500, a window WD, a protective film 700, a cover panel 910, and a cover spacer 920. The display apparatus DD as described with reference to FIG. 5 includes example aspects of the display apparatus DD as described herein, and repeated descriptions of like elements are omitted for brevity.

As described herein, the substrate 100 may include first and second areas 1A and 2A facing different directions, and the substrate 100 may include a third area 3A located between the first and second areas 1A and 2A.

The first area 1A may include the display area DA. The first area 1A may include a portion of the non-display area NDA outside the display area DA in addition to the display area DA.

The display layer DISL, the thin-film encapsulation layer 300, the sensor layer 400, the light-transmitting adhesive layer 510, the polarizing film 500, and the window WD may be stacked in the first area 1A.

The display layer DISL may include the thin-film transistor TFT, the display element 200, and insulating layers therebetween, which are shown in FIG. 4 described above. The thin-film encapsulation layer 300 may be formed in the display area DA and the non-display area NDA in the first area 1A such that the thin-film encapsulation layer 300 covers the display layer DISL.

The sensor layer 400 may be provided on the thin-film encapsulation layer 300 in the first area 1A. The polarizing film 500 may be provided on the sensor layer 400.

The light-transmitting adhesive layer 510 may be between the polarizing film 500 and the sensor layer 400. The light-transmitting adhesive layer 510 may include an optically clear adhesive (OCA). However, the disclosure is not limited thereto, and the light-transmitting adhesive layer 510 may include optically clear resin (OCR). In some embodiments, the light-transmitting adhesive layer 510 may include a pressure sensitive adhesive (PSA). The PSA may include a polymer cured material. The PSA may include an acrylic or rubber-based adhesive. In some embodiments, the PSA may include an adhesive obtained by adding fine particles such as, for example, zirconia to the acrylic or rubber-based adhesive.

In an embodiment, the display apparatus may omit or be absent (may not include) the polarizing film 500. For example, the display apparatus may include a filter plate including a black matrix and color filters instead of the polarizing film 500.

The window WD may be disposed on the polarizing film 500. The window WD may provide a display surface to a user and protect components underneath the window WD. As described above, the light-transmitting adhesive layer 510 may be disposed between the window WD and the polarizing film 500. The window WD may be arranged to correspond to the display area DA of the first area 1A of the substrate 100, the non-display area NDA, and the third area 3A that is bent.

A panel driver 800 may be disposed in the second area 2A. The panel driver 800 may be connected to a pad portion of the substrate 100 and may supply a data signal and a scan signal to a gate line and a data line. The panel driver 800 may be spaced apart from a bending protection layer 600. The panel driver 800 may be, for example, a driver integrated circuit (IC) and may be mounted on the pad portion of the substrate 100. In some aspects, the pad portion may be directly electrically connected to the driver IC.

In another embodiment, a flexible circuit board 810 may be mounted on a pad portion of the substrate 100, and a driving integrated circuit may be mounted on the flexible circuit board 810. The flexible circuit board 810 may use a chip on film (COF) or a flexible printed circuit (FPC). A driver IC, which supplies signals for making light emit from a plurality of display elements 200 in the display area DA, may be mounted on the flexible circuit board 810. Aspects of the present disclosure support various modifications to the flexible circuit board 810, such as, for example, both the panel driver 800 and the flexible circuit board 810 being disposed in the second area 2A.

The third area 3A of the substrate 100 is located between the first area 1A and the second area 2A, and may be bent such that the third area 3A in the bent state has a certain inner radius. A connection line CWL may be disposed on the third area 3A, and the bending protection layer 600 may be disposed on the connection line CWL. The connection line CWL may transmit signals provided from the panel driver 800 and/or the flexible circuit board 810 to the display area DA of the first area 1A. The bending protection layer 600 may protect the connection line CWL and may be a stress neutralization layer. By positioning a stress neutral plane near the connection line CWL through the bending protection layer 600, the tensile stress applied to the connection line CWL may be reduced. In some embodiments, the bending protection layer 600 may be omitted.

The substrate 100 may have a first surface 100a and a second surface 100b located on the opposite side of the first surface 100a. The first surface 100a of the substrate 100 may refer to the front surface of the substrate 100, and the second surface 100b may refer to the rear surface of the substrate 100. The display layer DISL including display elements 200 may be located on the first surface 100a of the substrate 100. The protective film 700 may be located on the second surface 100b of the substrate 100 opposite to the first surface 100a on which the display layer DISL is located, that is, on a surface where images are not displayed.

The protective film 700 may be applied to the second surface 100b of the substrate 100 in the form of a coating (e.g., the second surface 100b may be coated with a material for forming the protective film 700) or may be attached to the second surface 100b in the form of a film. The protective film 700 may be attached to the second surface 100b of the substrate 100 to protect the display apparatus. For example, the protective film 700 may absorb physical shock from the outside or prevent impurities or moisture from penetrating into the display layer DISL. The protective film 700 may be patterned. The protective film 700 may be located in the first area 1A and the second area 2A of the substrate 100. The protective film 700 may be located outside of (e.g., may not be located in) the third area 3A that is bent. As the display panel DP is bent in the third area 3A, a portion of the protective film 700 and another portion of the protective film 700 may be arranged to face each other.

The cover panel 910 may be disposed on the back of a portion of the protective film 700. In an embodiment, an adhesive layer (not shown) may be disposed between the protective film 700 and the cover panel 910. The cover panel 910 may protect the display panel DP from external impacts and other physical forces or damage.

The cover panel 910 may function to relieve external shock and may include a cushion layer including an elastically deformable material. For example, the cover panel 910 may include a single-layered or multi-layered cushion layer including at least one material selected from the group consisting of thermoplastic elastomer, polystyrene, polyolefin, polyurethane thermoplastic elastomer, polyamide, synthetic rubber, polydimethylsiloxane, polybutadiene, polyisobutylene, poly(styrene-butadiene-styrene), polyurethanes, polychloroprene, polyethylene, silicone, and a combination of any of the materials. In some aspects, the cover panel 910 may include a material having elasticity as long as the material does not affect the image display of the display panel DP. For example, the material may have characteristics that do not negatively impact (e.g., within a threshold amount) the display of images by the display panel DP.

In some aspects, the cover panel 910 may further include, on the back of the display panel DP, a high-strength plate (e.g., a metal plate), graphite, a copper plate, and/or a heat dissipation plate supportive of stably supporting the display panel DP.

As an example, the cover panel 910 may include an embossing layer (not shown), an absorption layer (not shown), and a support member (not shown), which are sequentially disposed on the rear surface of the display panel DP. However, the configuration of the cover panel 910 is not limited thereto, and the cover panel 910 may further include additional elements having various functions supportive of features of the cover panel 910 and/or the display panel DP. In some aspects, the mutual positions (e.g., stacking order) of elements constituting the cover panel 910 may vary based on embodiments. For example, in an embodiment, the embossing layer, the absorption layer, and the support member are sequentially disposed on the back of the display panel DP, but in another embodiment, the support member may be disposed first on the back of the display panel DP and the embossing layer and/or the absorption layer may be disposed on the back of the support member.

The embossing layer may include a plurality of embossed patterns that alleviate and disperse external shocks or the like (e.g., other electrical events), and may include a single layer or multiple layers. The absorption layer may be filled with air or a dispersing material or sound-absorbing material to absorb external shocks or the like, and may include a single layer or multiple layers. The embossing layer and the absorption layer may be formed separately and bonded to each other through an adhesive or glue. However, the disclosure is not limited thereto, and the embossing layer and the absorption layer may be formed as a single layer.

The support member may include a high-strength and/or high-ductility material supportive of securing or improving the mechanical strength of the display apparatus DD. As an example, the support member may be a metal plate including at least one type of metal or alloy. The support member may have sufficient strength by having a thickness ranging from about 10 μm to about hundreds of μm. Accordingly, the mechanical strength of the display apparatus DD may be secured or improved at least by the support member.

The cover spacer 920 may maintain a uniform gap between the cover panel 910 and an area of the display panel DP corresponding to the second area 2A when the display panel DP is bent, thereby controlling the degree of bending (or curvature) of the display panel DP. In some aspects, the cover spacer 920 may support an area of the display panel DP corresponding to the second area 2A when the first area 1A and the second area 2A face each other when the display panel DP is bent. In an embodiment, the cover spacer 920 may include the same material as the cover panel 910, but is not limited thereto. For example, the cover spacer 920 may include an elastic material suitable for the design conditions of the display panel DP.

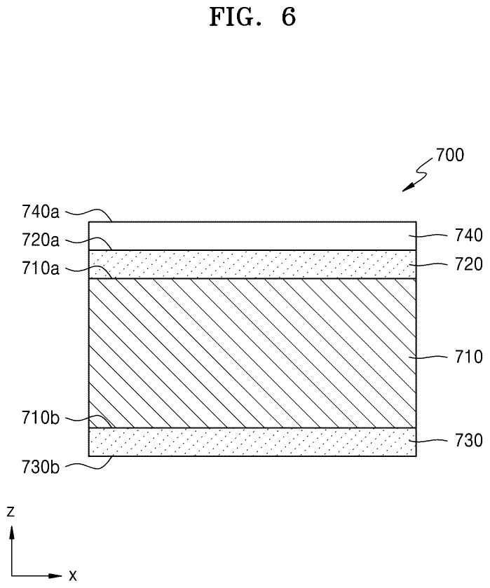

FIG. 6 is a cross-sectional view of a protective film 700 included in a display apparatus according to an embodiment.

Referring to FIG. 6, the protective film 700 may include a base layer 710, a first conductive layer 720, a second conductive layer 730, and an adhesive layer 740. The base layer 710 may have a first surface 710a and a second surface 710b located on the opposite side of the first surface 710a. The first conductive layer 720 may be located on the first surface 710a of the base layer 710. The second conductive layer 730 may be located on the second surface 710b of the base layer 710. The adhesive layer 740 may be disposed on a first surface 720a of the first conductive layer 720. The adhesive layer 740 may be located between the first conductive layer 720 and the substrate 100 (see FIG. 5). The adhesive layer 740 of the protective film 700 may be attached to the second surface 100b (see FIG. 5) of the substrate 100 (see FIG. 5) of the display panel DP.

The base layer 710 may include a polymer resin. For example, the base layer 710 may include polyethylene terephthalate (PET) or polyimide (PI). In some aspects, the base layer 710 may include a transparent material supportive of increasing transmittance in the light-transmitting hole area H (see FIG. 1) overlapping a camera, an IR sensor, or the like.

In some embodiments, the base layer 710 may omit or be absent (may not include) organic nanoparticles or inorganic nanoparticles. For example, the base layer 710 may not include silica particles. As a comparative example, in some other display apparatuses, the display apparatuses may include a base layer that includes organic nanoparticles or inorganic nanoparticles to increase productivity in the manufacturing process. The organic nanoparticles or inorganic nanoparticles included in the base layer may induce light scattering, thereby reducing light transmittance. However, in the present embodiment, the base layer 710 is absent (does not include) organic nanoparticles and inorganic nanoparticles, and thus, the transmittance of the protective film 700 may be improved.

In an embodiment, the haze of the protective film 700 may be greater than 0.05% and less than 0.45%. As the transmittance of the protective film 700 is improved, the transmittance in the light-transmitting hole area H (see FIG. 1) overlapping an IR sensor or the like may be improved. IR sensor performance of the display apparatus may be improved.

In an embodiment, the surface resistance of the base layer 710 may be about 10¹³ Ω/sq or more. Preferably, for example, the surface resistance of the base layer 710 may be about 10¹³ Ω/sq to about 1015 Ω/sq.

In an embodiment, the base layer 710 may have a thickness of about 25 μm to about 125 μm. In an example in which the thickness of the base layer 710 is less than 25 μm, the thickness may result in decreased productivity and a decrease in the panel protection effect of the protective film 700. In an example in which the thickness of the base layer 710 exceeds 125 μm, the thickness may result in increased costs.

The first conductive layer 720 may be disposed on the first surface 710a of the base layer 710. In an embodiment, the first conductive layer 720 may be disposed directly on the first surface 710a of the base layer 710. The first conductive layer 720 may include a conductive polymer and/or a transparent conductive oxide. The first conductive layer 720 may include a conductive polymer, such as, for example, poly(p-phenylene), polypyrrole, polythiophene, polyparaphenylene vinylene, polyacetylene, polyaniline, poly(3,4-ethylenedioxythiophene), or poly(3,4-ethylenedioxythiophene) poly(styrene sulfonate) (PEDOT: PSS). Alternatively, the first conductive layer 720 may be, for example, a transparent electrode material and may include at least one transparent conductive oxide selected from the group including indium tin oxide, indium zinc oxide, zinc oxide, indium oxide, indium gallium oxide, and aluminum zinc oxide. The first conductive layer 720 may include a transparent material supportive of improving the transmittance of the protective film 700. In an embodiment, the first conductive layer 720 may include PEDOT: PSS.

In an embodiment, the surface resistance of the first conductive layer 720 may be about 30 Ω/sq to about 10⁶ Ω/sq. For example, the surface resistance of the first conductive layer 720 may refer to the surface resistance of the first surface 720a of the first conductive layer 720.

In an embodiment, the first conductive layer 720 may have a thickness of about 0.01 μm to about 0.5 μm. Preferably, the first conductive layer 720 may have a thickness of about 0.05 μm to about 0.2 μm. In some cases, if the thickness of the first conductive layer 720 is less than 0.01 μm, productivity may decrease, and if the thickness of the first conductive layer 720 is more than 0.5 μm, costs may increase. In the above thickness range of about 0.05 μm to about 0.2 μm, the first conductive layer 720 may have a surface resistance of about 30 Ω/sq to about 10⁶ Ω/sq.

The second conductive layer 730 may be disposed on the second surface 710b of the base layer 710. In an embodiment, the second conductive layer 730 may be disposed directly on the second surface 710b of the base layer 710. The second conductive layer 730 may include a conductive polymer and/or a transparent conductive oxide. In an embodiment, the second conductive layer 730 may include the same material as the first conductive layer 720. However, the disclosure is not limited thereto, and the second conductive layer 730 may include a material that is different from a material of the first conductive layer 720. In an embodiment, the second conductive layer 730 may include PEDOT: PSS.

In an embodiment, the surface resistance of the second conductive layer 730 may be about 30 Ω/sq to about 10⁶ Ω/sq. In some aspects, the surface resistance of the second conductive layer 730 may refer to the surface resistance of the second surface 730b of the second conductive layer 730.

In an embodiment, the second conductive layer 730 may have a thickness of about 0.01 μm to about 0.5 μm. Preferably, for example, the second conductive layer 730 may have a thickness of about 0.05 μm to about 0.2 μm. In the thickness range of about 0.05 μm to about 0.2 μm, the second conductive layer 730 may have a surface resistance of about 30 Ω/sq to about 10⁶ Ω/sq

The adhesive layer 740 may be disposed on the first conductive layer 720. In an embodiment, the adhesive layer 740 may be disposed directly on the first surface 720a of the first conductive layer 720. In an embodiment, the adhesive layer 740 may include a PSA. The PSA may include a polymer cured product. The PSA may include an acrylic or rubber-based adhesive, or an adhesive obtained by adding fine particles such as, for example, zirconia to the acrylic or rubber-based adhesive. In another embodiment, the adhesive layer 740 may include an OCA. However, the disclosure is not limited thereto, and in some embodiments, the adhesive layer 740 may include an OCR. In some aspects, the adhesive layer 740 may include a light-transmitting material. In some embodiments, the adhesive layer 740 may further include an ultraviolet (UV)-sensitive material.

The adhesive layer 740 may be absent (may not include) per- and polyfluoroalkyl substances (PFAS). For example, the adhesive layer 740 may be absent (may not include) perfluorohexanoic acid (PFHxA). PFAS is a substance that may be added to the adhesive layer 740 for the purpose of preventing static electricity. However, PFAS is a hazardous substance that does not decompose easily and accumulates in the human body and the environment, and the use of the PFAS may be restricted in the future in countries, such as, for example, the European Union (EU).

In an embodiment, the adhesive layer 740 may have a thickness of about 3 μm to about 30 μm. Preferably, for example, the adhesive layer 740 may have a thickness of about 3 μm to about 25 μm. In an example in which the thickness of the adhesive layer 740 exceeds 30 μm, securing a process for bonding the flexible circuit board may be difficult.

In an embodiment, the surface resistance of the adhesive layer 740 may be 10¹⁰ Ω/sq or less. Preferably, for example, the surface resistance of the adhesive layer 740 may be about 10³ Ω/sq to 10¹⁰ Ω/sq. For example, the surface resistance of the adhesive layer 740 may refer to the surface resistance of the first surface 740a of the adhesive layer 740.

In an embodiment, when the second conductive layer 730 is disposed on the second surface 710b of the base layer 710 and the first conductive layer 720 is disposed on the first surface 710a of the base layer 710, charge transfer from the adhesive layer 740 to the first conductive layer 720 or the second conductive layer 730 may be facilitated. Because the first conductive layer 720 located between the base layer 710 and the adhesive layer 740 includes a conductive material, the resistance of the first conductive layer 720 may be lower than the resistance of the adhesive layer 740. Accordingly, charges may move in a vertical direction (e.g., z direction or −z direction) from the adhesive layer 740 toward the first conductive layer 720, and the surface resistance of the adhesive layer 740 may decrease. Accordingly, the adhesive layer 740 may have low surface resistance without including PFAS. In a display apparatus DD in which the adhesive layer 740 of the protective film 700 is attached to the bottom of the substrate 100 (see FIG. 5), electrostatic discharge defects may be reduced.

In an embodiment, with respect to the entirety of the protective film 700, the fluorine (F) content of the protective film 700 may be less than 0.25 ppb. The F content of the protective film 700 may be greater than 0 and less than 0.25 ppb. In some embodiments, the protective film 700 may not include F.

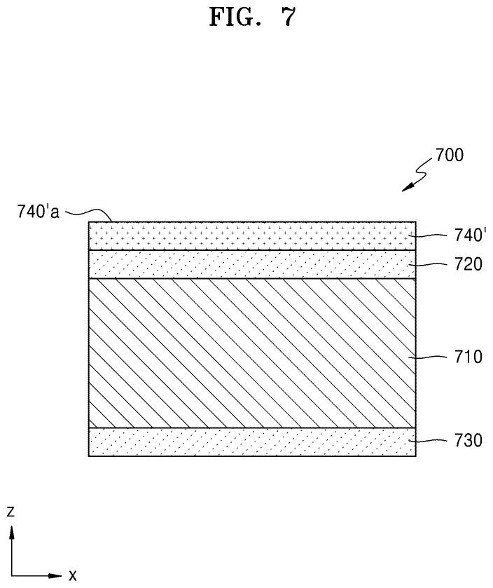

FIG. 7 is a cross-sectional view of a protective film 700 included in a display apparatus according to an embodiment. The protective film 700 described with reference to FIG. 7 includes aspects of the protective film 700 described herein with reference to FIG. 6, and repeated descriptions of like elements are omitted for brevity. FIG. 7 is different from the embodiment described with reference to FIG. 6 in the configuration of an adhesive layer 740′. Hereinafter, the differences between the adhesive layer 740′ and the adhesive layer 740 are mainly described, and repeated descriptions are omitted.

Referring to FIG. 7, a protective film 700 may include a base layer 710, a first conductive layer 720, a second conductive layer 730, and an adhesive layer 740′.

In an embodiment, the adhesive layer 740′ may include conductive molecules, polar molecules, and/or zwitterions.

The adhesive layer 740′ may include conductive molecules, such as, for example, poly(p-phenylene), polypyrrole, polythiophene, polyparaphenylene vinylene, polyacetylene, polyaniline, poly(3,4-ethylenedioxythiophene), or PEDOT: PSS. Alternatively, or additionally, the adhesive layer 740′ may include polar molecules, such as, for example, polyoxyethylene alkylamine, polyoxyethylene alkylamine fatty acid ester, glycerin fatty acid ester, sorbitan fatty acid ester, polyoxyethylene sorbitan fatty acid ester, polyoxyethylene alkylphenyl ester, or polyoxyethylene glycol fatty acid ester. Alternatively, or additionally, the adhesive layer 740′ may include zwitterions, such as, for example, alkyl betaine.

In an example in which the adhesive layer 740′ includes such conductive molecules, polar molecules, and/or zwitterions, the inclusion of such conductive molecules, polar molecules, and/or zwitterions may promote charge movement in a direction (e.g., −z direction or z direction) from the adhesive layer 740′ toward the first conductive layer 720. Accordingly, in an example in which the adhesive layer 740′ includes conductive molecules, polar molecules, and/or zwitterions, the surface resistance of the adhesive layer 740′ may be reduced. The surface resistance of the adhesive layer 740′ may refer to the surface resistance of a first surface 740′a of the adhesive layer 740′.

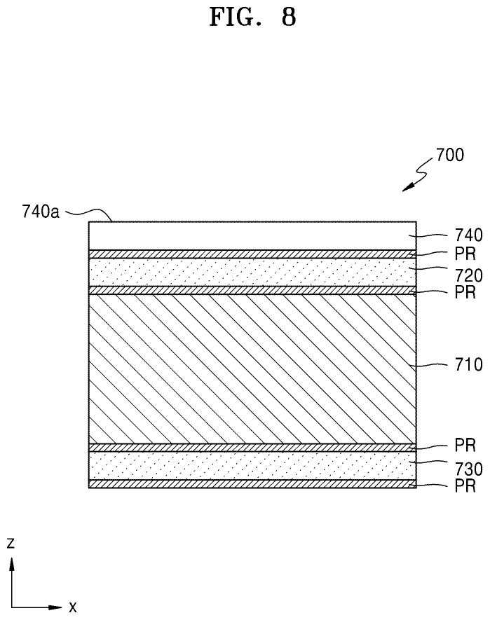

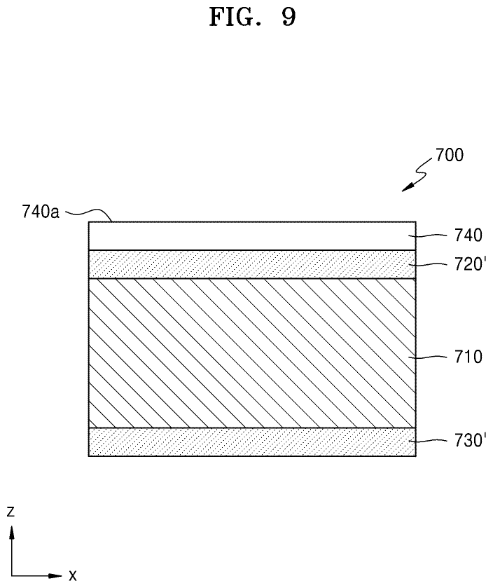

FIGS. 8 and 9 are cross-sectional views of a protective film 700 included in a display apparatus according to an embodiment. The protective film 700 described with reference to FIGS. 8 and 9 includes aspects of the protective film 700 described herein with reference to FIG. 6, and repeated descriptions of like elements are omitted for brevity. FIGS. 8 and 9 are modified examples of FIG. 6, and hereinafter, the description will focus on differences, and repeated descriptions are omitted.

Referring to FIG. 8, a protective film 700 may include a base layer 710, a first conductive layer 720, a second conductive layer 730, and an adhesive layer 740, and primer layers PR may be disposed on both sides of the first conductive layer 720 and both sides of the second conductive layer 730, respectively.

Each of the primer layers PR may include a primer material, such as, for example, acrylate resin, acrylic urethane, or epoxy urethane. The primer layer PR may increase the interfacial adhesion between the first conductive layer 720 or the second conductive layer 730 and the base layer 710.

In an embodiment, as illustrated in FIG. 8, the primer layers PR are provided as separate layers from the first conductive layer 720 and the second conductive layer 730, but the disclosure is not limited thereto. Referring to FIG. 9, in another embodiment, a first conductive layer 720′ may include a conductive polymer and/or a transparent conductive oxide. In some aspects, the first conductive layer 720′ may further include a primer material. Similarly, for example, a second conductive layer 730′ may include a conductive polymer and/or a transparent conductive oxide. The second conductive layer 730′ may further include a primer material.

### Embodiments and Comparative Examples

Below, aspects supported by the present disclosure will be described in more detail through example embodiments and comparative examples. However, the following embodiments and comparative examples are intended to describe the present disclosure in more detail, and the scope of the present disclosure is not limited by the following embodiments and comparative examples. The following embodiments and comparative examples may be appropriately modified and changed by those skilled in the art within the scope of the present disclosure.

### Embodiment 1

The protective film 700 according to an embodiment may include a base layer 710, a first conductive layer 720, a second conductive layer 730, and an adhesive layer 740. The base layer 710 may include PET and may be formed to have a thickness of 75 μm. The first conductive layer 720 may include PEDOT: PSS and may include an acrylate resin as a primer material. The second conductive layer 730 may include PEDOT: PSS and may include an acrylate resin as a primer material. The first conductive layer 720 may be formed such that a thickness of the first conductive layer 720 is 0.06 μm, and the second conductive layer 730 may be formed such that a thickness of the second conductive layer 730 is 0.06 μm. The adhesive layer 740 may include acrylic resin. The adhesive layer 740 may be formed such that a thickness of the adhesive layer 740 is 13 μm.

### Embodiment 2

The protective film 700 according to an embodiment may include a base layer 710, a first conductive layer 720, a second conductive layer 730, and an adhesive layer 740′. The base layer 710 may include PET and may be formed such that a thickness of the base layer 710 is 75 μm. The first conductive layer 720 may include PEDOT: PSS and may include an acrylate resin as a primer material. The second conductive layer 730 may include PEDOT: PSS and may include an acrylate resin as a primer material. The first conductive layer 720 may be formed such that a thickness of the first conductive layer 720 is 0.06 μm, and the second conductive layer 730 may be formed such that a thickness of the second conductive layer 730 is 0.06 μm. The adhesive layer 740′ may include acrylic resin and alkyl betaine, which is a zwitterion. The adhesive layer 740′ may be formed such that a thickness of the adhesive layer 740′ is 13 μm.

### Comparative Example

A protective film according to a comparative example may include a base layer, a conductive layer, and an adhesive layer. The adhesive layer may be disposed on a first surface of the base layer. The adhesive layer may be in direct contact with the first surface of the base layer. The conductive layer may be disposed on only one side of the base layer. The conductive layer may be disposed on a second surface located opposite to the first surface of the base layer. The base layer may include PET and may include silica nanoparticles. The base layer may be formed such that a thickness of the base layer is 75 μm. The conductive layer may include PEDOT/PSS. The conductive layer may be formed such that a thickness of the conductive layer is 0.06 μm. The adhesive layer may include acrylic resin and bis(trifluoromethanesulfonyl)imide, which is PFAS, at a content of 50 ppb. The adhesive layer may be formed such that a thickness of the adhesive layer is 13 μm.

TABLE 1

| | | | Comparative |
|---|---|---|---|
| Division | Embodiment 1 | Embodiment 2 | example |
| Haze (%) | 0.44 | 0.28 | 2.9 |

TABLE 2

| | | | Comparative |
|---|---|---|---|
| Division | Embodiment 1 | Embodiment 2 | example |
| Surface resistance | 5.1*10⁹ | 2.1*10⁷ | 9.1*10¹⁰ |
| (Ω/sq) | | | |

Table 1 shows results obtained by measuring the transparency of the protective films of Embodiment 1, Embodiment 2, and Comparative Example. The haze of the protective films of Embodiment 1, Embodiment 2, and Comparative Example was measured in a wavelength range of about 900 nm to about 1000 nm by using Lambda 1050+ (PerkinELmer), which is haze measurement equipment.

By examining Table 1, it may be seen that the haze was reduced in Embodiments 1 and 2 compared to the Comparative Example. According to an embodiment, because the base layer 710 of the protective film 700 is absent (does not include) inorganic nanoparticles, such as, for example, silica nanoparticles, and organic nanoparticles, the transparency of the protective film 700 may be improved.

Table 2 shows results obtained by measuring the surface resistances of adhesive layers of the protective films of Embodiment 1, Embodiment 2, and Comparative Example. Surface resistance was measured at two randomly selected locations on the first surface of each of the adhesive layers, and an average value was derived. The surface resistance was measured using a TREK 152-1 and a test voltage of 100V.

Referring to Table 2, it may be seen that Embodiments 1 and 2 have surface resistances that are comparable to or less than the surface resistance of the Comparative Example. According to an embodiment, because the first conductive layer 720 and second conductive layers 730 are disposed on both sides of the base layer 710 of the protective film 700, and in particular, the first conductive layer 720 is disposed between the base layer 710 and the adhesive layer 740, the adhesive layer 740 may have low surface resistance without including PFAS. Accordingly, the protective film 700 according to an embodiment may reduce static electricity phenomenon. In a display apparatus DD in which the protective film 700 according to an embodiment is attached to the bottom of the substrate 100 (see FIG. 5), electrostatic discharge defects may be reduced.

According to one or more embodiment of the disclosure, because a protective film includes a base layer, a conductive layer disposed on both sides of the base layer, and an adhesive layer disposed on one side of the conductive layer and the adhesive layer includes conductive molecules, polar molecules, and/or zwitterions, a display apparatus with reduced electrostatic discharge defects may be implemented. However, the scope of the disclosure is not limited by these effects.

Embodiments of the present disclosure support one or more processes (methods, flowcharts) supportive of the features and embodiments described herein. Descriptions that an element “may be disposed,” “may be formed,” and the like include processes (methods, flowcharts) and techniques for disposing, forming, positioning, and modifying the element and the like in accordance with example aspects described herein.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a display layer located on a first surface of the substrate and comprising a display element; and
a protective film located on a second surface of the substrate, wherein the second surface of the substrate is opposite to the first surface of the substrate, and
wherein the protective film comprises:
a base layer that is transparent;
a first conductive layer located on a first surface of the base layer;
a second conductive layer located on a second surface of the base layer, wherein the second surface of the base layer is opposite to the first surface of the base layer; and
an adhesive layer between the first conductive layer and the substrate, wherein the adhesive layer comprises at least one of conductive molecules, polar molecules, and zwitterions.

2. The display apparatus of claim 1, wherein the base layer comprises polyethylene terephthalate or polyimide.

3. The display apparatus of claim 1, wherein the base layer is absent organic nanoparticles and inorganic nanoparticles.

4. The display apparatus of claim 1, wherein a surface resistance of the first conductive layer is about 30 Ω/sq to about 10⁶ Ω/sq.

5. The display apparatus of claim 1, wherein the first conductive layer and the second conductive layer each comprise a conductive polymer or a transparent conductive oxide.

6. The display apparatus of claim 1, wherein a thickness of each of the first conductive layer and the second conductive layer is about 0.01 μm to about 0.5 μm.

7. The display apparatus of claim 1, wherein a thickness of the adhesive layer is about 3 μm to about 30 μm.

8. The display apparatus of claim 1, wherein a surface resistance of the adhesive layer is about 10³ Ω/sq to about 10¹⁰ Ω/sq.

9. The display apparatus of claim 1, wherein a fluorine (F) content of the protective film is less than 0.25 ppb.

10. A display apparatus comprising:
a substrate;
a display element disposed on a front surface of the substrate;
an encapsulation member covering the display element; and
a protective film disposed on a rear surface of the substrate,
wherein the protective film comprises:
a base layer that is transparent;
a first conductive layer disposed on a front surface of the base layer;
a second conductive layer disposed on a rear surface of the base layer; and
an adhesive layer between the first conductive layer and the substrate,
wherein the adhesive layer comprises at least one of conductive molecules, polar molecules, and zwitterions, and a surface resistance of the adhesive layer is about 10¹⁰ Ω/sq or less.

11. The display apparatus of claim 10, wherein:
the substrate comprises a first area facing a first direction, a second area extending from the first area and facing a second direction different from the first direction, and a third area located between the first area and the second area;
the display element is disposed on the first area; and
the protective film comprises a portion located in the first area and another portion spaced apart from the portion and located in the second area.

12. The display apparatus of claim 10, further comprising:
an optical member on the encapsulation member; and
a window on the optical member.

13. The display apparatus of claim 10, wherein the base layer comprises polyethylene terephthalate or polyimide.

14. The display apparatus of claim 10, wherein the base layer is absent organic nanoparticles and inorganic nanoparticles.

15. The display apparatus of claim 10, wherein a surface resistance of the first conductive layer is about 30 Ω/sq to about 10⁶ Ω/sq.

16. The display apparatus of claim 10, wherein the first conductive layer and the second conductive layer each comprise a conductive polymer or a transparent conductive oxide.

17. The display apparatus of claim 10, wherein the first conductive layer and the second conductive layer each have a thickness of about 0.01 μm to about 0.5 μm.

18. The display apparatus of claim 10, wherein the adhesive layer has a thickness of about 3 μm to about 30 μm.

19. The display apparatus of claim 1, wherein a surface resistance of the adhesive layer is about 10³ Ω/sq to about 10¹⁰ Ω/sq.

20. The display apparatus of claim 1, wherein a fluorine (F) content of the protective film is less than 0.25 ppb.
